(19) United States
(12) Patent Application Publication
(10) Pub. No.: US 2016/0313393 A1
(43) Pub. Date: Oct. 27, 2016

(54) MULTILAYER CIRCUIT BOARD AND TESTER INCLUDING THE SAME

(71) Applicant: Murata Manufacturing Co., Ltd., Kyoto (JP)

(72) Inventor: Tadaji Takemura, Kyoto (JP)

(21) Appl. No.: 15/202,220

(22) Filed: Jul. 5, 2016

Related U.S. Application Data
(63) Continuation of application No. PCT/JP2015/050011, filed on Jan. 5, 2015.

(30) Foreign Application Priority Data
Jan. 6, 2014 (JP) 2014-000088

(51) Int. Cl. G01R 31/28; H05K 1/11; H05K 1/03; G01R 1/073; H05K 1/02

(52) U.S. Cl. CPC G01R 31/2886; G01R 1/07314; H05K 1/0268; H05K 1/0298; H05K 1/0306; H05K 1/0313; H05K 1/115; H05K 1/0271; H05K 2201/09781

(57) ABSTRACT

Interfacial delamination of a resin multilayer body from a ceramic multilayer body that occurs in a multilayer circuit board composed of a ceramic multilayer body and a resin multilayer body thereon is reduced, and the warpage of the multilayer circuit board is reduced. A multilayer circuit board includes a ceramic multilayer body that is a stack of multiple ceramic layers and a resin multilayer body that is a stack of multiple resin insulating layers to and is on the ceramic multilayer body. The resin multilayer body contains dummy electrode pads for relaxing shrinkage stress in the resin multilayer body. This lessens the stress on the interface between the ceramic multilayer body and the resin multilayer body because the dummy electrode pads work to prevent the resin multilayer body from shrinking.

### BACKGROUND

### Technical Field

The present disclosure relates to a multilayer circuit board composed of ceramic layers and resin insulating layers and to a tester that includes this multilayer circuit board.

A tool commonly used in electrical inspections of semiconductor devices such as LSI devices is a probe card, which is a card composed of a ceramic multilayer substrate and probe pins thereon. In recent years, the increased integration of semiconductor devices and the resulting increase in number and reduced pitch of their terminals have led to the use of multilayer circuit boards, which are ceramic multilayer substrates in which some layers have been replaced with resin insulating layers, such as polyimide layers, for easy formation of delicate wiring.

For example, a multilayer circuit board 100 described in Patent Document 1 includes, as illustrated in FIG. 12, a ceramic multilayer body 101 that is a stack of multiple ceramic layers 101a and a resin multilayer body 102 that is a stack of multiple resin insulating layers 102a, with the resin multilayer body 102 on the ceramic multilayer body 101. On the top surface of the multilayer circuit board 100, there are multiple tightly pitched surface electrodes 103 each to be connected to a probe pin. On the bottom surface of the multilayer circuit board 100, there are back electrodes 104 corresponding to the surface electrodes 103 and each connected to the corresponding surface electrode 103. The back electrodes 104 are for connection to an external device-mounted substrate.

In the resin multilayer body 102 and the ceramic multilayer body 101, there is a rewiring structure that makes the pitch between adjacent back electrodes 104 wider than that between adjacent surface electrodes 103.

The formation of such a rewiring structure requires that the wires that form the wiring in the resin multilayer body 102, which is closer to the surface electrodes 103, be thin and tightly pitched. The resin multilayer body 102 is thus composed of resin insulating layers 102a made of resin such as polyimide so that delicate wiring can be formed therein. The ceramic multilayer body 101 is composed of ceramic layers 101a, which are more rigid than the resin insulating layers 102a and have a coefficient of linear expansion close to those of test media, e.g., IC wafers, because of the relatively large room in it for wiring to be formed. This configuration of the multilayer circuit board 100 makes it possible to increase the number of terminals and electrical inspections of the semiconductor devices in which terminals have become tightly pitched in recent years.

Patent Document 1: Japanese Unexamined Patent Application Publication No. 2011-9694 (see paragraphs 0019 to 0022, FIG. 1, etc.)

### BRIEF SUMMARY

The known multilayer circuit board 100 is a stack of a ceramic multilayer body 101 and a resin multilayer body 102, and this stacked structure causes, for example, residual stress that remains in the multilayer circuit board 100 to occur during the formation of the resin multilayer body 102 on the ceramic multilayer body 101 because of cure shrinkage of the resin multilayer body 102.

Residual stress in the multilayer circuit board 100 can lead to delamination at the interface between the ceramic multilayer body 101 and the resin multilayer body 102 and/or warping of the multilayer circuit board 100.

Made in light of the above problem, the present disclosure is intended to reduce the interfacial delamination of a resin multilayer body from a ceramic multilayer body that occurs in a multilayer circuit board composed of a ceramic multilayer body and a resin multilayer body thereon and to reduce the warpage of the multilayer circuit board.

A multilayer circuit board according to the present disclosure includes a ceramic multilayer body that is a stack of a plurality of ceramic layers and a resin multilayer body that is a stack of a plurality of resin insulating layers and is on the ceramic multilayer body. The circuit board is characterized by at least one dummy conductor in the resin multilayer body for relaxing shrinkage stress in the resin multilayer body.

In this case, the resin multilayer body contains dummy conductor(s) for relaxing shrinkage stress in the resin multilayer body, and the dummy conductor(s) works to prevent the resin multilayer body from shrinking during the formation of the resin multilayer body on the ceramic multilayer body. This reduces the stress on the interface between the ceramic and resin multilayer bodies, thereby reducing interfacial delamination of the resin multilayer body from the ceramic multilayer body.

The reduced stress on the interface between the ceramic and resin multilayer bodies, furthermore, leads to reduced warpage of the multilayer circuit board.

The at least one dummy conductor can be located at the periphery of the resin multilayer body in plan view. The plan view is a view seen in a direction perpendicular to a top surface of the resin multilayer body. At the interface between the ceramic and resin multilayer bodies, the stress caused by the shrinkage of the resin multilayer body is higher at the periphery than at the center. Delamination at this interface therefore starts at the perimeter of the interface in many cases. The dummy conductor(s) is thus positioned at the periphery of the resin multilayer body in plan view, or in other words near the point where interfacial delamination of the ceramic multilayer body from the resin multilayer body starts. This leads to efficient relaxation of the stress on this point, thereby helping to reduce interfacial delamination of the resin multilayer body from the ceramic multilayer body and the warpage of the multilayer circuit board.

The at least one dummy conductor may be at least one dummy conductive via. A dummy conductor becomes more effective in reducing interfacial delamination of the ceramic multilayer body from the resin multilayer body and the warpage of the multilayer circuit board increases with its increasing volume. The use of a dummy conductive via is an easy way to increase the volume of the dummy conductor as compared with, for example, the use of an in-plane dummy conductor and therefore provides a way to reduce the aforementioned interfacial delamination and the warpage of the multilayer circuit board with ease.

The at least one dummy conductive via may be multiple dummy conductive vias of which at least one pair are in point symmetry around the center of the resin multilayer body in plan view. When the resin multilayer body undergoes cure shrinkage, the resin multilayer body, in plan view for example, shrinks in the direction from its perimeter toward its center. If the positions of dummy conductors are not symmetric around the center of the resin multilayer body in plan view, the reduction of shrinkage in the parts of the resin multilayer body where the dummy conductors exist is greater than that in the parts opposite, with respect to the center, the areas where the resin multilayer body has the dummy conductors. The resulting imbalance in the reduction of shrinkage within the resin multilayer body causes the multilayer circuit board to warp. Arranging at least one pair of dummy conductive vias in point symmetry around the center of the resin multilayer body in plan view will ensure balanced reduction of shrinkage in the areas of the resin multilayer body where the at least one pair of dummy conductive vias exist, thereby reducing the warpage of the multilayer circuit board.

The resin multilayer body may be rectangular in plan view with there being a dummy conductive via at each of the four corners thereof in plan view. When the resin multilayer body is rectangular in plan view, the likely point for interfacial delamination of the resin multilayer body from the ceramic multilayer body to start is the four corners of the resin multilayer body because the shrinkage stress that works when the resin multilayer body shrinks is strongest at these four corners. Placing a dummy conductive via at each of the four corners of the resin multilayer body relaxes the shrinkage stress on the four corners and therefore will reduce delamination of the resin multilayer body from the ceramic multilayer body. This arrangement also leads to reduced warpage of the multilayer circuit board because the dummy conductive vias are in point symmetry around the center of the resin multilayer body in plan view.

The multilayer circuit board may further include, in the resin multilayer body, an in-plane conductor to which a first dummy conductive via is connected. This improves the effectiveness of the dummy conductive via in relaxing the shrinkage stress in the resin multilayer body as compared with cases where it is not connected to an in-plane conductor because the in-plane conductor improves the adhesion of the dummy conductive via to the resin multilayer body.

The multilayer circuit board may further include a second dummy conductive via different from the first dummy conductive via and connected to the in-plane conductor. In this case, multiple dummy conductors for relaxing shrinkage stress in the resin multilayer body are connected to an in-plane conductor, which leads to more effective reduction of shrinkage stress in the resin multilayer body.

The multilayer circuit board may further include a first conductive via in the ceramic multilayer body and a second conductive via in the resin multilayer body with an end face of the first conductive via connected to an end face of the second conductive via. In this case, a junction of the first and second conductive vias have strength of adhesion higher than the strength of the adhesion between the resin and ceramic multilayer bodies is formed at the interface between the resin and ceramic multilayer bodies, and the junction reinforces the strength of the adhesion between the resin and ceramic multilayer bodies. The firm connection between the first and second conductive vias also allows the second conductive via in the resin multilayer body to serve as a support that prevents the resin multilayer body from shrinking, thereby reducing interfacial delamination of the resin multilayer body from the ceramic multilayer body.

The junction of the first and second conductive vias may be located at the periphery of the resin multilayer body in plan view. In this case, the periphery of the interface between the resin and ceramic multilayer bodies, at which shrinkage stress in the resin multilayer body is strong, is reinforced by the junction of the first and second conductive vias, which further reduces interfacial delamination of the resin multilayer body from the ceramic multilayer body.

A predetermined dummy conductive via may be connected to the end face of the second conductive via opposite the one connected to the first conductive via so that the first and second conductive vias and the predetermined dummy conductor are positioned to overlap in plan view. This translates into supporting a dummy conductive via for relaxing shrinkage stress in the resin multilayer body with the first conductive via in the ceramic multilayer body, thereby allowing the dummy conductive via to serve as a support that prevents the resin multilayer body from shrinking together with the second conductive via.

The end face of the first conductive via opposite the one connected to the second conductive via may be connected to an electrode pad disposed in the ceramic multilayer body. This leads to reduced warpage of the multilayer circuit board because the electrode pad reduces the warpage of the ceramic multilayer body.

The volume of the at least one dummy conductor may be greater than that of the second conductive via. This improves the effectiveness of the dummy conductive via(s) in relaxing the shrinkage stress in the resin multilayer body as compared with cases where the dummy conductor and the second conductive via have the same volume, thereby reducing each of interfacial delamination of the resin multilayer body from the ceramic multilayer body, the warpage of the multilayer circuit board, and an increase in the resistance of an in-plane conductor due to poor flatness of the resin multilayer body.

The area in plan view of the resin multilayer body may be smaller than that of the ceramic multilayer body. The shrinkage stress that works on the periphery of the interface between the resin and ceramic multilayer bodies, the point at which delamination of this interface starts, when the resin multilayer body shrinks becomes higher with increasing area in plan view of the resin multilayer body. Making the area in plan view of the resin multilayer body smaller than that of the ceramic multilayer body will therefore reduce interfacial delamination of the resin multilayer body from the ceramic multilayer body as compared with cases where both multilayer bodies have the same area in plan view.

One or both of the two end faces of the dummy conductive via or at least one of the dummy conductive vias may be connected to an electrode pad disposed in the resin multilayer body. This improves the effectiveness of the dummy conductive via(s) in reducing the shrinkage stress in the resin multilayer body as compared with cases where it is (they are) not connected to an electrode pad because the electrode pad improves the adhesion of the dummy conductive via(s) to the resin multilayer body.

Each of the ceramic layers may be a ceramic green sheet in which the main component is a ceramic that contains borosilicate glass. In this case, the ceramic layers that form the ceramic multilayer body can be low-temperature co-fired ceramic (LTCC). Furthermore, metals such as Ag, which is a low-resistance conductor, can be used for the in-plane conductors and other wiring electrodes formed in the ceramic multilayer body.

The ceramic multilayer body may further include an anti-shrink layer that prevents the ceramic layers from shrinking during firing. In this case, the warpage of the ceramic multilayer body is reduced, and that of the multilayer circuit board is reduced accordingly.

The multilayer circuit board may further include multiple top connection electrodes on the top surface of the resin multilayer body and bottom connection electrodes on the bottom surface of the resin multilayer body corresponding to the top connection electrodes and each connected to the corresponding top connection electrode with a wiring structure in the ceramic and resin multilayer bodies formed to make the pitch between adjacent bottom connection electrodes wider than that between adjacent top connection electrodes. In this case, assuming a multilayer circuit board with a rewiring structure formed therein, each of interfacial delamination of its resin multilayer body from its ceramic multilayer body, the warpage of the multilayer circuit board, and an increase in the resistance of the wiring in the resin multilayer body due to the warping of the resin multilayer body are reduced.

This multilayer circuit board may be used in a tester for semiconductor devices. In this case, the multilayer circuit board can be prepared for use as a probe card by, for example, coupling a probe pin to each of top connection electrodes.

According to the present disclosure, the resin multilayer body contains dummy conductor(s) for relaxing shrinkage stress in the resin multilayer body, and the dummy conductor(s) works to prevent the resin multilayer body from shrinking during the formation of the resin multilayer body on the ceramic multilayer body. This leads to decreased stress on the interface between the ceramic and resin multilayer bodies. As a result, interfacial delamination of the resin multilayer body from the ceramic multilayer body is reduced.

The decreased stress on the interface between the ceramic and resin multilayer bodies, furthermore, leads to reduced warpage of the multilayer circuit board.

### BRIEF DESCRIPTION OF THE SEVERAL VIEWS OF THE DRAWINGS

FIG. 1 is a cross-sectional view of a multilayer circuit board according to Embodiment 1 of the present disclosure.

FIG. 2 is a cross-sectional view of a multilayer circuit board according to Embodiment 2 of the present disclosure.

FIG. 3 is a cross-sectional view of a multilayer circuit board according to Embodiment 3 of the present disclosure.

FIG. 4 is a cross-sectional view of a multilayer circuit board according to Embodiment 4 of the present disclosure.

FIG. 5 is a cross-sectional view of a multilayer circuit board according to Embodiment 5 of the present disclosure.

FIG. 6 is a plan view of the multilayer circuit board of FIG. 5.

FIG. 7 illustrates a variation of the arrangement of dummy conductive vias in FIG. 5.

FIG. 8 is a cross-sectional view of a multilayer circuit board according to Embodiment 6 of the present disclosure.

FIG. 9 is a cross-sectional view of a multilayer circuit board according to Embodiment 7 of the present disclosure.

FIG. 10 is a cross-sectional view of a multilayer circuit board according to Embodiment 8 of the present disclosure.

FIG. 11 is a cross-sectional view of a multilayer circuit board according to Embodiment 9 of the present disclosure.

FIG. 12 is a cross-sectional view of a known multilayer circuit board.

### DETAILED DESCRIPTION

### Embodiment 1

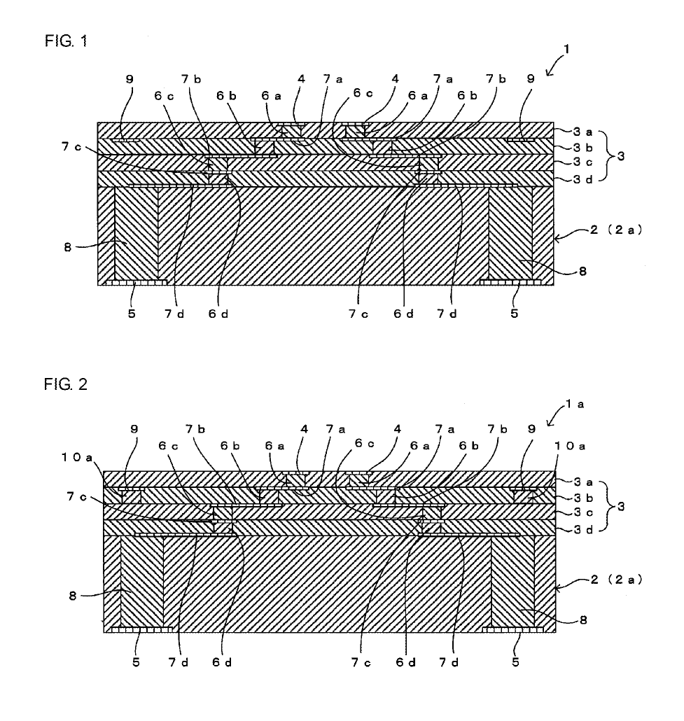

A multilayer circuit board 1 according to Embodiment 1 of the present disclosure is described with reference to FIG. 1. FIG. 1 is a cross-sectional view of the multilayer circuit board 1. FIG. 1 illustrates only the parts relevant to the present disclosure and omits all other parts.

The multilayer circuit board 1 according to this embodiment includes, as illustrated in FIG. 1, a ceramic multilayer body 2 that is a stack of multiple ceramic layers 2a and a resin multilayer body 3 that is a stack of multiple resin insulating layers 3a to 3d and is on the ceramic multilayer body 2. On the top surface of the uppermost resin insulating layer 3a of the resin multilayer body 3, which is also the top surface of the multilayer circuit board 1, there are multiple top connection electrodes 4. On the bottom surface of the ceramic multilayer body 2, which is also the bottom surface of the multilayer circuit board 1, there are multiple bottom connection electrodes 5 corresponding to the top connection electrodes 4 and each connected to the corresponding top connection electrode 4.

There are multiple top connection electrodes 4 between the two top connection electrodes 4 in FIG. 1, and there are multiple bottom connection electrodes 5 between the two bottom connection electrodes 5. Each top connection electrode 4 and the corresponding bottom connection electrode 5 are connected by inner wiring composed of multiple conductive vias 6a to 6d and 8 and in-plane conductors 7a to 7d formed inside the resin multilayer body 3 and the ceramic multilayer body.

The pitch between adjacent bottom connection electrodes 5 is wider than that between adjacent top connection electrodes 4. Thus there is in the ceramic multilayer body 2 and the resin multilayer body 3 a rewiring structure formed by the lines of inner wiring that connect the top connection electrodes 4 to the corresponding bottom connection electrodes 5.

Each of the ceramic layers 2a in the ceramic multilayer body 2 can be a ceramic green sheet made from a low-temperature co-fired ceramic (LTCC) in which the main component is a ceramic (e.g., alumina) that contains borosilicate glass. The ceramic layers 2a can also be made from other various ceramic materials such as high-temperature co-fired ceramics (HTCCs).

The ceramic multilayer body 2 may have an anti-shrink layer between adjacent ceramic layers 2a that prevents the ceramic layers 2a from shrinking during firing. This anti-shrink layer can be a ceramic material that does not shrink at the temperature at which the ceramic layers 2a are fired. This reduces the warpage of the fired ceramic multilayer body 2, and the warpage of the multilayer circuit board 1 is reduced accordingly.

The bottom connection electrodes 5 on the bottom surface of the ceramic multilayer body 2 are each formed through, for example, a printing technique that uses a conductive paste that contains a metal such as Ag, Al, or Cu. The surface of each bottom connection electrode 5 may be plated with Ni/Au.

The in-plane conductors 7d on the top surface of the ceramic multilayer body 2, and inner in-plane conductors, omitted in the drawing, are each formed on a main surface of a ceramic layer 2a through, for example, a printing technique that uses a conductive paste that contains a metal such as Ag, Al, or Cu. In this embodiment, each of the in-plane conductors 7d and the omitted in-plane conductors is made of Ag.

The conductive vias 8 in the ceramic multilayer body 2 in FIG. 1 are continuous bodies each composed of via elements formed in the individual ceramic layers 2a. Each of the via elements is formed by, for example, creating a through-hole in the ceramic layer 2a using a laser or any other device and filling this through-hole with a conductive paste that contains any of Ag, Al, Cu, and so forth using a printing technique.

The resin insulating layers 3a to 3d that form the resin multilayer body 3 are each made of a thermosetting resin such as polyimide or glass epoxy resin. The Young's modulus of the resin insulating layers 3a to 3d is smaller than that of the ceramic layers 2a; the ceramic layers 2a have a Young's modulus of approximately 220 GPa, whereas, for example, resin insulating layers 3a to 3d made of polyimide have 1 to 5 GPa.

The top connection electrodes 4 on the top surface of resin multilayer body 3 and the in-plane conductors 7a to 7c and conductive vias 6a to 6d in the resin multilayer body 3 can each be made of any of metals such as Cu, Ag, and Al. Each of the in-plane conductors 7a to 7c is on a main surface of a predetermined one of the resin insulating layers 3a to 3d.

The multilayer circuit board 1 configured in this way is produced by preparing the ceramic multilayer body 2 and then placing the resin multilayer body 3 on the ceramic multilayer body 2. During the curing of the resin multilayer body 3 on the ceramic multilayer body 2, residual stress that remains in the multilayer circuit board 1 occurs because of cure shrinkage of the resin multilayer body 3. This residual stress leads to events such as interfacial delamination of the ceramic multilayer body 2 from the resin multilayer body 3 and warping of the multilayer circuit board 1.

The reason why the interfacial delamination of the ceramic multilayer body 2 from the resin multilayer body 3 occurs is that when the strength of adhesion is compared among the interfaces between adjacent ceramic layers 2a, those between adjacent resin insulating layers 3a to 3d, and that between a ceramic layer 2a and the adjoining resin insulating layer 3d, the weakest is the adhesion at the interface between a ceramic layer 2a and the resin insulating layer 3d because these two layers have different material compositions. At the interface between a ceramic layer 2a and the resin insulating layer 3d, the aforementioned residual stress is stronger at the periphery than at the center. The interfacial delamination of the ceramic multilayer body 2 from the resin multilayer body 3 therefore starts at the periphery of the interface in many cases.

In this embodiment, there are multiple dummy electrode pads 9 (corresponding to the “at least one dummy conductor” in the present disclosure) in the region in the resin multilayer body 3 where the in-plane conductors 7a to 7c and the conductive vias 6a to 6d do not exist. The electrode pads 9, each of which is not related to the wiring in the multilayer circuit board 1, are electrodes for relaxing the shrinkage stress that occurs when the resin multilayer body 3 is cured. The dummy electrode pads 9 are each located at the periphery of the resin multilayer body 3 in plan view, i.e., a region in the resin multilayer body 3 where the aforementioned residual stress is high. The above positions of the dummy electrode pads 9 are merely an example and can be changed to anywhere in the vacant space within the resin multilayer body 3 as needed. The number of pads placed can also be changed as necessary.

A tester according to the present disclosure includes the above multilayer circuit board 1 and multiple probe pins connected to the top connection electrodes 4 on the top surface of the multilayer circuit board 1. The tester is, for example, a probe card for wafer testing of devices such as semiconductor devices (e.g., LSI devices) that have yet to be diced. More specifically, this probe card determines whether the electrical characteristics of LSI chips are acceptable or not by making contact with the bonding pads of the LSI chips at the tips of the probe pins.

The following describes a method for the production of the multilayer circuit board 1. The production method described below can be applied to the multilayer circuit boards 1a to 1h described hereinafter, which are multilayer circuit boards according to other embodiments.

First, a ceramic multilayer body 2 is prepared. Ceramic layers 2a that have been individually prepared are stacked in a predetermined order, and the resulting stack is pressed and fired to form the ceramic multilayer body 2. The via elements for conductive vias 8 in the individual ceramic layers 2a are each formed by, for example, creating a via hole through the ceramic layer 2a by laser machining and filling the via hole with a conductive paste that contains any metal selected from Cu, Ag, and Al using a printing technique. The other conductive vias, or the conductive vias excluding the via elements, are also formed in the same way. The in-plane conductors 7d on a main surface of the ceramic layers 2a can be formed through a printing technique that uses a conductive paste that contains any metal selected from Cu, Ag, and Al (Ag in this embodiment).

The resin multilayer body 3 can be formed by the build-up method or thin-film stacking. In the build-up method, a resin insulating layer 3d with copper foil is placed on the top surface of the prepared ceramic multilayer body 2, and then in-plane conductors 7c and conductive vias 6d are formed. The resin insulating layer 3d can be made of materials such as glass epoxy resin and polyimide. The in-plane conductors 7c are obtained by patterning the copper foil using etching. The conductive vias 6d are formed by, for example, creating via holes through the resin insulating layer 3d by laser machining and subjecting the via holes to an appropriate process such as via-fill plating with a metal such as Cu, Ag, or Al.

Then placing resin insulating layers 3a to 3c with copper foil, forming conductive vias, and forming in-plane conductors are repeated in the same way on a layer-by-layer basis to give the multilayer circuit board 1. On the resin insulating layer 3b, dummy electrode pads 9 are formed together with in-plane conductors 7a. The top connection electrodes 4 can each be formed by the same method as the in-plane conductors 7a to 7c.

When thin-film stacking is used to form the resin multilayer body 3, the prepared ceramic multilayer body 2 is coated with a resin insulating layer 3d through, for example, the application of polyimide. The resin insulating layer 3d is photolithographically patterned to create conductive vias 6d therethrough, and then in-plane conductors 7c are formed on the layer. The in-plane conductors 7c can be formed by, for example, making a Ti film as a base electrode on the resin insulating layer 3d through sputtering or any other technique, making a Cu film on the Ti film in the same way through sputtering or any other technique, and then making another Cu film on the Cu film through electrolytic or electroless plating.

Then applying polyimide from which the resin insulating layers 3a to 3c are made, forming conductive vias, and forming in-plane conductors are repeated in the same way on a layer-by-layer basis to give the multilayer circuit board 1. On the resin insulating layer 3b, dummy electrode pads 9 are formed together with in-plane conductors 7a. The top connection electrodes 4 can be formed by the same method as the in-plane conductors 7a to 7c.

The top connection electrodes 4 and the bottom connection electrodes 5 may be coated with a Ni/Au film by electrolytic or electroless plating.

This way of forming the resin multilayer body 3 by the build-up method or thin-film stacking allows for the formation of sophisticated patterns for the top connection electrodes 4 and the in-plane conductors 7a to 7c as compared with in-plane conductors formed on the ceramic multilayer body 2 using a printing technique (e.g., the in-plane conductors 7d).

In the above embodiment, therefore, the resin multilayer body 3 contains dummy electrode pads 9 for relaxing shrinkage stress in the resin multilayer body 3, and the dummy electrode pads 9 work to prevent the resin multilayer body 3 from shrinking during the formation of the resin multilayer body 3 on the ceramic multilayer body 2. This reduces the stress on the interface between the ceramic multilayer body 2 and the resin multilayer body 3, thereby reducing interfacial delamination of the resin multilayer body 3 from the ceramic multilayer body 2.

The reduced stress on the interface between the ceramic multilayer body 2 and the resin multilayer body 3, furthermore, leads to reduced warpage of the multilayer circuit board 1. The reduced warpage of the multilayer circuit board 1 leads to improved flatness of the in-plane conductors 7a to 7c formed in the resin multilayer body 1. As a result, an increase in resistance due to bending of the in-plane conductors 7a to 7c is reduced.

As stated above, at the interface between the ceramic multilayer body 2 and the resin multilayer body 3, the residual stress caused by cure shrinkage of the resin multilayer body 3 is higher at the periphery than at the center, and delamination at this interface starts at the perimeter of the interface in many cases. Positioning the dummy electrode pads 9 at the periphery of the resin multilayer body 3 in plan view, or in other words near the point where interfacial delamination of the ceramic multilayer body 2 from the resin multilayer body 3 starts, leads to efficient relaxation of the stress on this point, thereby helping to reduce interfacial delamination of the resin multilayer body 3 from the ceramic multilayer body 2 and the warpage of the multilayer circuit board 1.

Each of the ceramic layers 2a is a low-temperature co-fired ceramic (a ceramic green sheet) in which the main component is a ceramic that contains borosilicate glass, and this allows the manufacturer to use metals such as Ag, which is a low-resistance conductor, for the in-plane conductors and other wiring electrodes formed in the ceramic multilayer body 2.

In the multilayer circuit board 1 according to this embodiment, there is a rewiring structure in the ceramic multilayer body 2 and the resin multilayer body 3 that makes the pitch between adjacent bottom connection electrodes 5 wider than that between adjacent top connection electrodes 4. It should be noted that the tightly pitched top connection electrodes 4 are on the resin multilayer body 3 side, where it is easy to form delicate wiring.

The dummy electrode pads 9 in the resin multilayer body 3 reduce interfacial delamination of the ceramic multilayer body 2 from the resin multilayer body 3 and the warpage of the multilayer circuit board 1, which are both disadvantages that arise when a multilayer circuit board 1 is composed of a ceramic multilayer body 2 and a resin multilayer body 3. As a result, the multilayer circuit board 1 is suitable for use as a substrate for probe cards used in electrical testing of the semiconductor devices in recent years, in which the terminal pitch has been narrowing.

### Embodiment 2

A multilayer circuit board 1a according to Embodiment 2 of the present disclosure is described with reference to FIG. 2. FIG. 2 is a cross-sectional view of the multilayer circuit board 1a. FIG. 2 illustrates only the parts relevant to the present disclosure and omits all other parts.

The difference of the multilayer circuit board 1a according to this embodiment from the multilayer circuit board 1 of Embodiment 1 described with reference to FIG. 1 is, as illustrated in FIG. 2, that the multiple dummy conductors for relaxing shrinkage stress provided in the resin multilayer body 3 are composed of dummy electrode pads 9 and dummy conductive vias 10a. The other elements are the same as those in the multilayer circuit board 1 of Embodiment 1 and thus are given the same reference numerals to avoid duplicating description.

In this case, there are dummy conductive vias 10a in the resin insulating layer 3b positioned to overlap with the dummy electrode pads 9 in plan view, and the upper end faces of these dummy conductive vias 10a are connected to the dummy electrode pads 9.

A dummy conductor becomes more effective in reducing interfacial delamination of the ceramic multilayer body 2 from the resin multilayer body 3 and the warpage of the multilayer circuit board 1a with its increasing volume. The use of dummy conductors each composed of a dummy electrode pad 9 and a dummy conductive via 10a is an easy way to increase their volume as compared with cases where dummy electrode pads 9 alone are used as dummy conductors and therefore provides a way to reduce the aforementioned interfacial delamination and the warpage of the multilayer circuit board 1a with ease.

Furthermore, connecting the dummy conductive vias 10a to the dummy electrode pads 9 improves the effectiveness of the dummy conductive vias 10a in relaxing the shrinkage stress in the resin multilayer body 3 as compared with cases where the dummy conductive vias 10a are not connected to the dummy electrode pads because the dummy electrode pads 9 improve the adhesion of the dummy conductive vias 10a to the resin multilayer body 3.

The dummy conductors need not always be composed of a dummy electrode pad 9 and a dummy conductive via 10a; the dummy conductive vias 10a may be the only component.

Furthermore, the bottom end faces of the dummy conductive vias 10a may be connected to other electrode pads. In this case, the adhesion of the dummy conductive vias 10a to the resin multilayer body 3 is enhanced.

### Embodiment 3

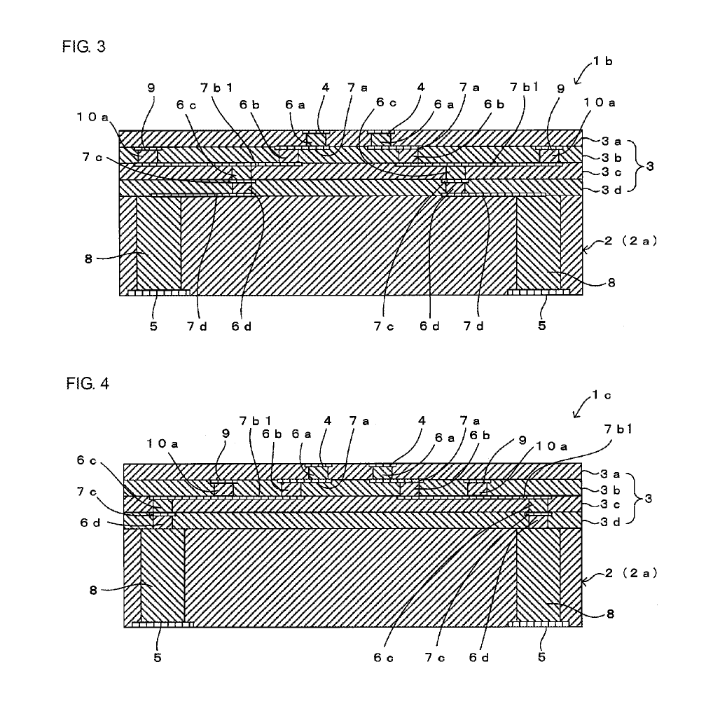

A multilayer circuit board 1b according to Embodiment 3 of the present disclosure is described with reference to FIG. 3. FIG. 3 is a cross-sectional view of the multilayer circuit board 1b. FIG. 3 illustrates only the parts relevant to the present disclosure and omits all other parts.

The difference of the multilayer circuit board 1b according to this embodiment from the multilayer circuit board 1a of Embodiment 2 described with reference to FIG. 2 is, as illustrated in FIG. 3, that in-plane conductors 7b1 on the top surface of the resin insulating layer 3c extend toward the dummy conductive vias 10a with the bottom end faces of the dummy conductive vias 10a connected to the in-plane conductors 7b1. The other elements are the same as those in the multilayer circuit board 1a of Embodiment 2 and thus are given the same reference numerals to avoid duplicating description.

Connecting the dummy conductive vias 10a to in-plane conductors 7b1 in this way improves the effectiveness of the dummy conductive vias 10a in relaxing the shrinkage stress in the resin multilayer body 3 as compared with cases where the dummy conductive vias 10a are not connected to in-plane conductors 7b1 because the in-plane conductors 7b1 improve the adhesion of the dummy conductive vias 10a to the resin multilayer body 3.

### Embodiment 4

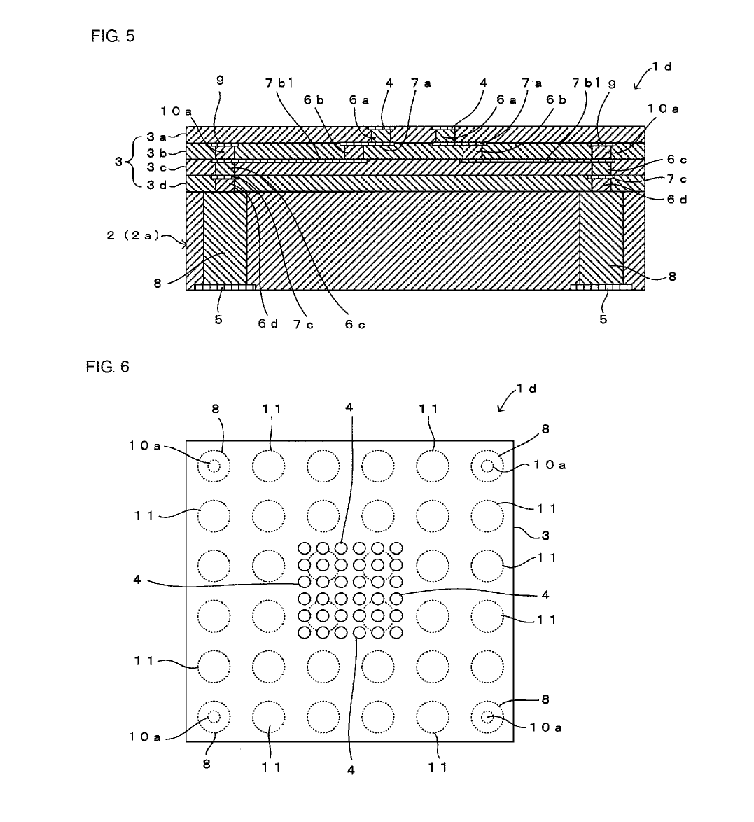

A multilayer circuit board 1c according to Embodiment 4 of the present disclosure is described with reference to FIG. 4. FIG. 4 is a cross-sectional view of the multilayer circuit board 1c. FIG. 4 illustrates only the parts relevant to the present disclosure and omits all other parts.

The differences of the multilayer circuit board 1c according to this embodiment from the multilayer circuit board 1b of Embodiment 3 described with reference to FIG. 3 are, as illustrated in FIG. 4, that an end face of the conductive vias 6d in the lowermost resin insulating layer 3d of the resin multilayer body 3 is connected to an end face of the conductive vias 8 in the ceramic multilayer body 2, and that the positions of the dummy conductors, which are composed of dummy electrode pads 9 and dummy conductive vias 10a, are different. The other elements are the same as those in the multilayer circuit board 1b of Embodiment 3 and thus are given the same reference numerals to avoid duplicating description.

In this case, the conductive vias 6d in the lowermost resin insulating layer 3d of the resin multilayer body 3 and the conductive vias 6c in the next resin insulating layer 3c are each positioned to overlap with the conductive vias 8 in the ceramic multilayer body 2 in plan view, with an end face of the conductive vias 8 in the ceramic multilayer body 2 connected to an end face of the conductive vias 6d in the lowermost resin insulating layer 3d. The conductive vias 6c in the resin insulating layer 3c and the conductive vias 6d in the resin insulating layer 3d are connected by in-plane conductors 7c.

In addition to this, the dummy conductors, which are composed of dummy electrode pads 9 and dummy conductive vias 10a, are connected to the in-plane conductors 7b1 that are on the top surface of the resin insulating layer 3c and connect the conductive vias 6c and 6b in the resin multilayer body 3. The conductive vias 8 in the ceramic multilayer body 2 in this embodiment correspond to the “first conductive via” in the present disclosure, and the conductive vias 6d in the resin multilayer body 3, which are connected to the top end faces of the conductive vias 8, correspond to the “second conductive via” in the present disclosure. In the following, the conductive vias 8 in the ceramic multilayer body 2 may be referred to as the first conductive vias 8, and the conductive vias 6d in the resin multilayer body 3 may be referred to as the second conductive vias 6d.

In such a configuration, junctions of the first conductive vias 8 in the ceramic multilayer body 2 and the second conductive vias 6d in the resin multilayer body 3 have strength of adhesion higher than the strength of the adhesion between the resin multilayer body 3 and the ceramic multilayer body 2 are formed at the interface between the resin multilayer body 3 and the ceramic multilayer body 2, and the junctions reinforce the strength of the adhesion between the resin multilayer body 3 and the ceramic multilayer body 2. The firm connection between the first conductive vias 8 and the second conductive vias 6d also allows the second conductive vias 6d in the resin multilayer body 3 to serve as supports that prevent the resin multilayer body 3 from shrinking, thereby reducing interfacial delamination of the resin multilayer body 3 from the ceramic multilayer body 2.

Furthermore, the junctions of the first conductive vias 8 and the second conductive vias 6d are located at the periphery of the resin multilayer body 3 in plan view. The periphery of the interface between the resin multilayer body 3 and the ceramic multilayer body 2, at which shrinkage stress in the resin multilayer body 3 is strong, is reinforced by the junctions of the first conductive vias 8 and the second conductive vias 6d. The junctions therefore reduce interfacial delamination of the resin multilayer body 3 from the ceramic multilayer body 2.

### Embodiment 5

A multilayer circuit board 1d according to Embodiment 5 of the present disclosure is described with reference to FIGS. 5 and 6. FIG. 5 is a cross-sectional view of the multilayer circuit board 1d, and FIG. 6 is a plan view of the multilayer circuit board 1d. FIGS. 5 and 6 illustrate only the parts relevant to the present disclosure and omit all other parts.

The difference of the multilayer circuit board 1d according to this embodiment from the multilayer circuit board 1c of Embodiment 4 described with reference to FIG. 4 is, as illustrated in FIG. 5, that the first conductive vias 8 in the ceramic multilayer body 2, the second conductive vias 6d in the resin multilayer body 3, the conductive vias 6c in the resin insulating layer 3c, which is next to the resin insulating layer 3d in which the second conductive vias 6d are present, and the dummy conductive vias 10a are each positioned to overlap in plan view. The other elements are the same as those in the multilayer circuit board 1c of Embodiment 4 and thus are given the same reference numerals to avoid duplicating description.

In this case, the dummy conductive vias 10a are connected to the end faces of the second conductive vias 6d opposite those connected to the first conductive vias 8 (the top and bottom end faces, respectively) by the in-plane conductors 7b1 between the dummy conductive vias 10a and the second conductive vias 6d, the conductive vias 6c, and the in-plane conductors 7c.

Furthermore, as illustrated in FIG. 6, the resin multilayer body 3 is rectangular in plan view, and there is a dummy conductive via 10a at each of the four corners of this rectangular resin multilayer body 3. Such an arrangement of the dummy conductive vias 10a can also be described as one in which a pair of dummy conductive vias 10a on the same diagonal line are in point symmetry around the center of the resin multilayer body 3 in plan view.

FIG. 6 also illustrates another plurality of conductive vias 11, which are located inside the ceramic multilayer body 2 and not illustrated in FIG. 5. These conductive vias 11 and the first conductive vias 8 are each connected to the corresponding bottom connection electrode 5.

In this embodiment, therefore, the dummy conductive vias 10a are positioned to overlap with both first conductive vias 8 and second conductive vias 6d in plan view and connected to the second conductive vias 6d, an end face of which is connected to an end face of the first conductive vias 8, by the conductive vias 6c and some other elements. Such a configuration gives the dummy conductive vias 10a, in addition to the capability to relax shrinkage stress in the resin multilayer body 3, the role as a support that works with the second conductive vias 6d to prevent the resin multilayer body 3 from shrinking.

When the resin multilayer body 3 undergoes cure shrinkage, the resin multilayer body 3, in plan view for example, shrinks in the direction from its perimeter toward its center. If, for example, there is a dummy conductive via 10a only at one of the four corners of the resin multilayer body 3 in plan view, shrinkage stress is greatly relaxed near the part of the resin multilayer body 3 where the dummy conductive via 10a exists and less near the other corners. The resulting imbalance in the amount of shrinkage stress relaxed within the resin multilayer body 3 can cause the multilayer circuit board 1 to warp.

Placing a dummy conductive via 10a at each of the four corners of the resin multilayer body 3 translates into arranging a pair of dummy conductive vias 10a on the same diagonal line of the resin multilayer body 3, which is rectangular in plan view, in point symmetry around the center of the resin multilayer body in plan view. The resulting balanced reduction of shrinkage by the dummy conductive vias 10a in the resin multilayer body 3 leads to reduced warpage of the multilayer circuit board 1d.

When the resin multilayer body 3 is rectangular in plan view, furthermore, the likely point for interfacial delamination of the resin multilayer body 3 from the ceramic multilayer body 2 to start is the four corners of the resin multilayer body 3 because the shrinkage stress that works when the resin multilayer body 3 shrinks is strongest at these four corners. Placing a dummy conductive via 10a at each of the four corners of the resin multilayer body 3 lessens the shrinkage stress on the four corners and therefore will reduce interfacial delamination of the resin multilayer body 3 from the ceramic multilayer body 2.

### (Variation of the Arrangement of the Dummy Conductive Vias 10a)

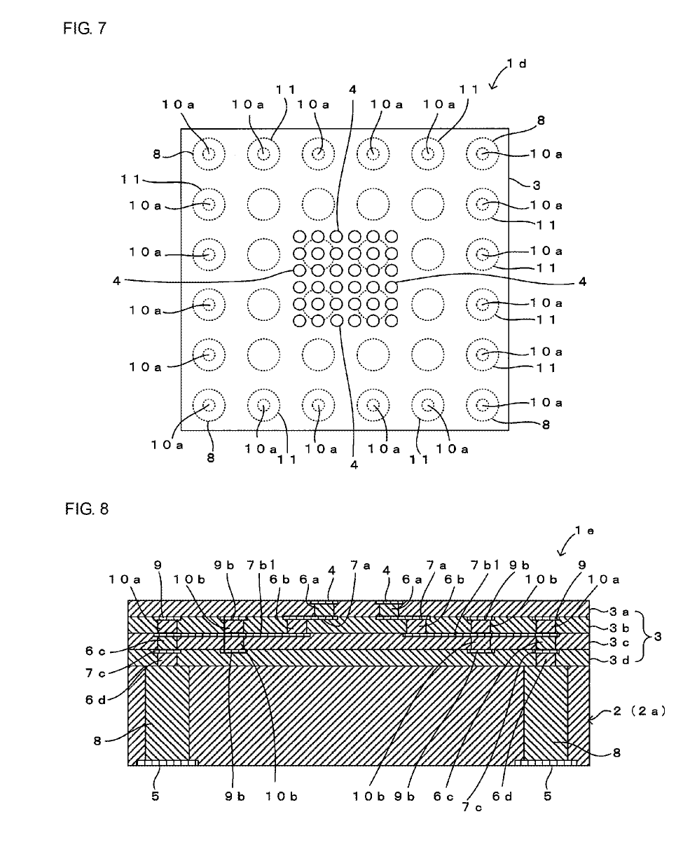

A variation of the arrangement of the dummy conductive vias 10a is described with reference to FIG. 7. FIG. 7 illustrates a variation of the arrangement of the dummy conductive vias 10a and corresponds to FIG. 6.

Although the above embodiment describes a case where there is a dummy conductive via 10a only at the four corners of a resin multilayer body 3 rectangular in plan view, it is also possible to, for example, arrange dummy conductive vias 10a at predetermined intervals along each peripheral side of the resin multilayer body 3 rectangular in plan view as illustrated in FIG. 7. This leads to more effective reduction of interfacial delamination of the resin multilayer body 3 from the ceramic multilayer body 2 because the dummy conductive vias 10a relax the cure shrinkage stress substantially across the entire area of the periphery, at which the aforementioned interfacial delamination starts.

Furthermore, the balanced arrangement (point-symmetric arrangement) of dummy conductive vias 10a at the periphery of the resin multilayer body 3 leads to reduced warpage of the multilayer circuit board 1d.

### Embodiment 6

A multilayer circuit board 1e according to Embodiment 6 of the present disclosure is described with reference to FIG. 8. FIG. 8 is a cross-sectional view of the multilayer circuit board 1e. FIG. 8 illustrates only the parts relevant to the present disclosure and omits all other parts.

The difference of the multilayer circuit board 1e according to this embodiment from the multilayer circuit board 1d of Embodiment 5 described with reference to FIG. 5 is, as illustrated in FIG. 8, that besides the dummy conductive vias 10a positioned to overlap with the first conductive vias 8 in the ceramic multilayer body 2 in plan view, there are dummy conductive vias 10b different from them. The other elements are the same as those in the multilayer circuit board 1d of Embodiment 5 and thus are given the same reference numerals to avoid duplicating description.

In this case, second dummy conductive vias 10b are additionally connected to the in-plane conductors 7b1 to which the bottom end faces of the dummy conductive vias 10a are connected. In this embodiment, there is one dummy conductive via 10b each above and below an in-plane conductor 7b1, and the two dummy conductive vias 10b are positioned to overlap in plan view. The end faces of the two dummy conductive vias 10b opposite the end faces connected to the in-plane conductors 7b1 are each connected to a dummy electrode pad 9b, and dummy conductors are each formed by these dummy conductive vias 10b and dummy electrode pads 9b.

Connecting multiple dummy conductors for relaxing shrinkage stress in the resin multilayer body 3 to an in-plane conductor 7b1 in this way leads to increased relaxation of shrinkage stress in the resin multilayer body 3 by dummy conductors, thereby further reducing interfacial delamination of the resin multilayer body 3 from the ceramic multilayer body 2 and the warpage of the multilayer circuit board 1e.

### Embodiment 7

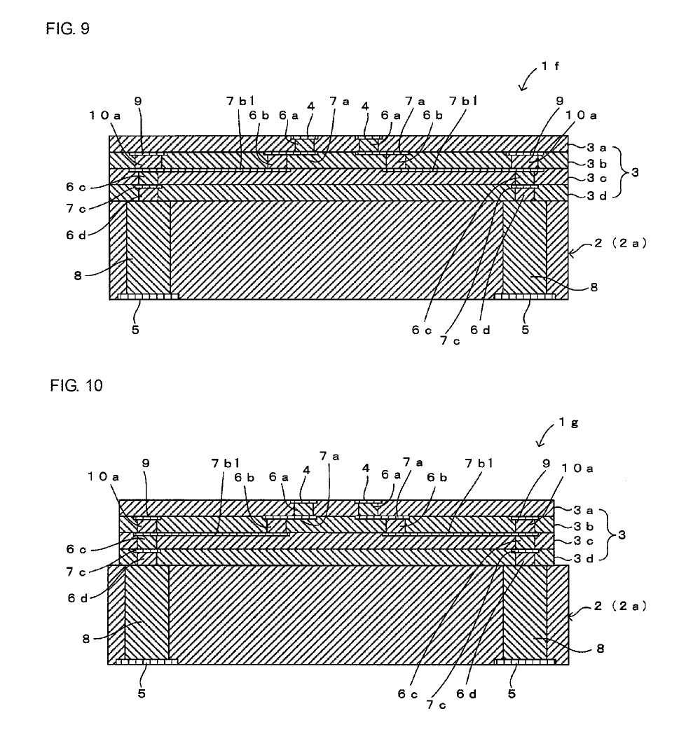

A multilayer circuit board 1f according to Embodiment 7 of the present disclosure is described with reference to FIG. 9. FIG. 9 is a cross-sectional view of the multilayer circuit board 1f. FIG. 9 illustrates only the parts relevant to the present disclosure and omits all other parts.

The difference of the multilayer circuit board 1f according to this embodiment from the multilayer circuit board 1d of Embodiment 5 described with reference to FIG. 5 is, as illustrated in FIG. 9, that the dummy conductive vias 10a have a greater volume than the conductive vias 6a to 6d formed in the resin multilayer body 3. The other elements are the same as those in the multilayer circuit board 1d of Embodiment 5 and thus are given the same reference numerals to avoid duplicating description.

This improves the effectiveness of the dummy conductive vias 10a in relaxing shrinkage stress in the resin multilayer body 3 as compared with cases where the dummy conductive vias 10a and the conductive vias 6a to 6d in the resin multilayer body 3 have the same volume, thereby reducing each of interfacial delamination of the resin multilayer body 3 from the ceramic multilayer body 2, the warpage of the multilayer circuit board 1f, and an increase in the resistance of the in-plane conductors 7a, 7b1, and 7c in the resin multilayer body 3 due to poor flatness of the resin multilayer body 3.

### Embodiment 8

A multilayer circuit board 1g according to Embodiment 8 of the present disclosure is described with reference to FIG. 10. FIG. 10 is a cross-sectional view of the multilayer circuit board 1g. FIG. 10 illustrates only the parts relevant to the present disclosure and omits all other parts.

The difference of the multilayer circuit board 1g according to this embodiment from the multilayer circuit board 1d of Embodiment 5 described with reference to FIG. 5 is, as illustrated in FIG. 10, that the resin multilayer body 3 has a smaller area in plan view than the ceramic multilayer body 2. The other elements are the same as those in the multilayer circuit board 1d of Embodiment 5 and thus are given the same reference numerals to avoid duplicating description.

The shrinkage stress that works on the periphery of the interface between the resin multilayer body 3 and the ceramic multilayer body 2, the point at which delamination of this interface starts, when the resin multilayer body 3 shrinks becomes higher with increasing area in plan view of the resin multilayer body 3. Making the area in plan view of the resin multilayer body 3 smaller than that of the ceramic multilayer body 2 will therefore reduce interfacial delamination of the resin multilayer body 3 from the ceramic multilayer body 2 as compared with cases where the resin multilayer body 3 and the ceramic multilayer body 2 have the same area in plan view.

### Embodiment 9

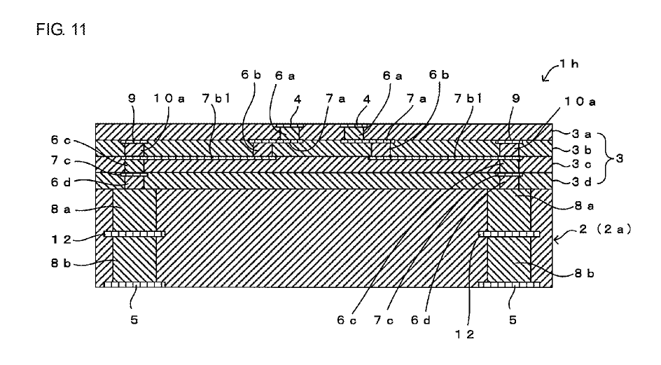

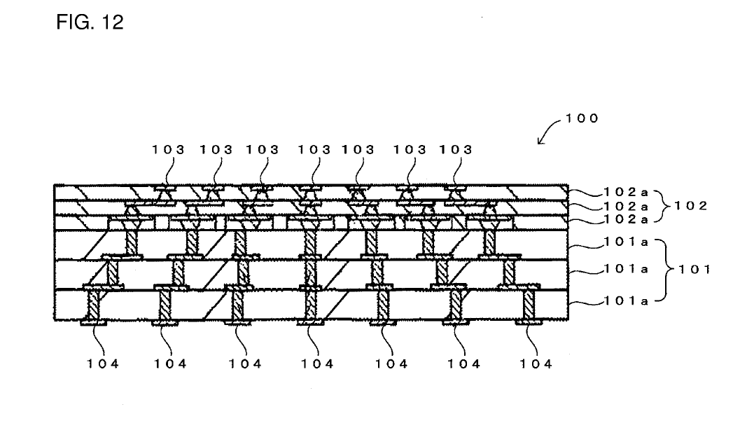

A multilayer circuit board 1h according to Embodiment 9 of the present disclosure is described with reference to FIG. 11. FIG. 11 is a cross-sectional view of the multilayer circuit board 1h. FIG. 11 illustrates only the parts relevant to the present disclosure and omits all other parts.

The difference of the multilayer circuit board 1h according to this embodiment from the multilayer circuit board 1d of Embodiment 5 described with reference to FIG. 5 is, as illustrated in FIG. 11, that conductive vias 8a in the ceramic multilayer body 2 (corresponding to the “first conductive via” in the present disclosure; the conductive vias 8a are hereinafter referred to as the first conductive vias 8a), an end face of which is connected to an end face of the second conductive vias 6d in the resin multilayer body 3, are connected to electrode pads 12 disposed inside the ceramic multilayer body 2 at their bottom end face. The other elements are the same as those in the multilayer circuit board 1d of Embodiment 5 and thus are given the same reference numerals to avoid duplicating description.

The first conductive vias 8 in Embodiment 5, illustrated in FIG. 5, extend through the ceramic multilayer body 2. In this embodiment, the first conductive vias 8a are shorter in length, and electrode pads 12 are connected to the bottom end faces, or the end faces opposite those connected to the second conductive vias 6d, of these first conductive vias 8a. Conductive vias 8b, which are another set of conductive vias, located between the electrode pads 12 and the bottom connection electrodes 5 and positioned to overlap with the first conductive vias 8a in plan view, connect the electrode pads 12 and the bottom connection electrodes 5. This further reduces the warpage of the ceramic multilayer body 2 as compared with cases where the first conductive vias 8 extend through the ceramic multilayer body 2 as in FIG. 5 because the electrode pads 12 improve the adhesion of the first conductive vias 8a and 8b to the ceramic multilayer body 2.

The present disclosure is not limited to the above embodiments. Besides the foregoing, various changes are possible unless they constitute departures from the gist of the disclosure. For example, although the above embodiments describe cases where the multilayer circuit boards 1 and 1a to 1h are composed of a ceramic multilayer body 2 and a resin multilayer body 3 placed on the top surface of the ceramic multilayer body 2, there may be a resin multilayer body 3 on both top and bottom surfaces of the ceramic multilayer body 2. This leads to reduced warpage of the multilayer circuit board because the shrinkage stress in the resin multilayer body 3 on the top surface of the ceramic multilayer body 2 cancels out that in the resin multilayer body 3 on the bottom surface.

It is also possible to combine configurations of the above embodiments into a multilayer circuit board.

### INDUSTRIAL APPLICABILITY

The present disclosure is applicable to various multilayer circuit boards that include a stack of a ceramic multilayer body and a resin multilayer body thereon.

### REFERENCE SIGNS LIST

1, 1a, 1b, 1c, 1d, 1e, 1f, 1g, 1h Multilayer circuit board
2 Ceramic multilayer body
2a Ceramic layers
3 Resin multilayer body
3a, 3b, 3c, 3d Resin insulating layer
4 Top connection electrode
5 Bottom connection electrode
6d Conductive via (second conductive via)
7a, 7b, 7b1, 7c In-plane conductor
8, 8a Conductive via (first conductive via)
9, 9b Dummy electrode pad (dummy conductor)
10a, 10b Dummy conductive via (dummy conductor)
12 Electrode pad

1. A multilayer circuit board comprising:
a ceramic multilayer body that is a stack of a plurality of ceramic layers; and
a resin multilayer body that is a stack of a plurality of resin insulating layers, the resin multilayer body being on the ceramic multilayer body,
the multilayer circuit board comprises at least one dummy conductor in the resin multilayer body that relaxes shrinkage stress in the resin multilayer body.

2. The multilayer circuit board according to claim 1, wherein the at least one dummy conductor is located at a periphery of the resin multilayer body in plan view.

3. The multilayer circuit board according to claim 1, wherein the at least one dummy conductor includes at least one dummy conductive via.

4. The multilayer circuit board according to claim 3, wherein:
the at least one dummy conductor includes a plurality of dummy conductive vias; and
at least a pair of dummy conductors is provided in point symmetry around a center of the resin multilayer body in plan view.

5. The multilayer circuit board according to claim 4, wherein:
the resin multilayer body is rectangular in plan view; and
there is a dummy conductive via at each of four corners of the resin multilayer body in plan view.

6. The multilayer circuit board according to claim 3, wherein:
the multilayer circuit board further includes an in-plane conductor in the resin multilayer body; and
a first dummy conductive via of the at least one dummy conductive via is connected to the in-plane conductor.

7. The multilayer circuit board according to claim 6, wherein:
the multilayer circuit board includes a second dummy conductive via different from the first dummy conductive via; and
the second dummy conductive via is connected to the in-plane conductor.

8. The multilayer circuit board according to claim 1, wherein:
the multilayer circuit board further includes a first conductive via in the ceramic multilayer body and
a second conductive via in the resin multilayer body; and
an end face of the first conductive via is connected to an end face of the second conductive via.

9. The multilayer circuit board according to claim 8, wherein a junction of the first and second conductive vias is located at a periphery of the resin multilayer body in plan view.

10. The multilayer circuit board according to claim 8, wherein a dummy conductive via is connected to an end face of the second conductive via opposite to the end face connected to the first conductive via so that the first and second conductive vias and the dummy conductor overlap in plan view.

11. The multilayer circuit board according to claim 8, wherein an end face of the first conductive via opposite to the end face connected to the second conductive via is connected to an electrode pad disposed in the ceramic multilayer body.

12. The multilayer circuit board according to claim 8, wherein a volume of the at least one dummy conductor is greater than a volume of the second conductive via.

13. The multilayer circuit board according to claim 1, wherein an area in plan view of the resin multilayer body is smaller than an area in plan view of the ceramic multilayer body.

14. The multilayer circuit board according to claim 3, wherein at least one of two end faces of the dummy conductive via is connected to an electrode pad disposed in the resin multilayer body.

15. The multilayer circuit board according to claim 1, wherein each of the plurality of ceramic layers is a ceramic green sheet in which a main component is a ceramic that contains borosilicate glass.

16. The multilayer circuit board according to claim 1, wherein the ceramic multilayer body further includes an anti-shrink layer that prevents the ceramic layers from shrinking during firing.

17. The multilayer circuit board according to claim 1, wherein:
the multilayer circuit board further includes a plurality of top connection electrodes on a top surface of the resin multilayer body and a plurality of bottom connection electrodes on a bottom surface of the resin multilayer body corresponding to the plurality of top connection electrodes and each connected to corresponding one of the plurality of top connection electrodes; and
there is a wiring structure in the ceramic multilayer bodies and resin multilayer bodies provided to make a pitch of the bottom connection electrodes wider than a pitch of the top connection electrodes.

18. A tester comprising the multilayer circuit board according to claim 1, wherein the tester inspects a semiconductor device.

19. The multilayer circuit board according to claim 4, wherein:
the multilayer circuit board further includes a first conductive via in the ceramic multilayer body and
a second conductive via in the resin multilayer body; and
an end face of the first conductive via is connected to an end face of the second conductive via.

20. The multilayer circuit board according to claim 19, wherein a predetermined dummy conductive via of the plurality of dummy conductive vias is connected to an end face of the second conductive via opposite to the end face connected to the first conductive via so that the first and second conductive vias and the predetermined dummy conductor overlap in plan view.
